(19) United States
(12) Patent Application Publication
(10) Pub. No.: US 2005/0138803 A1
(43) Pub. Date: Jun. 30, 2005

(54) Stamper for pattern transfer and manufacturing method thereof

(75) Inventors: Shuichi Okawa, Tokyo (JP); Kazuhiro Hattori, Tokyo (JP); Katsuyuki Nakada, Tokyo (JP); Mitsuru Takai, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TDK CORPORATION, Tokyo (JP)

(21) Appl. No.: 10/974,834

(22) Filed: Oct. 28, 2004

(30) Foreign Application Priority Data
Oct. 31, 2003 (JP) 2003-371804

(51) Int. Cl. B29C 35/00; H05K 1/03; A01J 21/00

(52) U.S. Cl. 29/846; 425/406; 425/810; 174/256

(57) ABSTRACT

In a stamper which is used as a mold for pattern transfer, the problem is resolved in such a manner that at least the convex extreme surface of the stamper is formed of a material 110 with no crystalline peak in X-ray diffraction. Such a stamper can be manufactured by the method comprising the steps of forming a convex-concave pattern on a substrate, forming, on the convex-concave pattern, a layer of a material 110 with no crystalline peak in X-ray diffraction, and removing the layer of the material with no crystalline peak in X-ray diffraction from said substrate and convex-concave pattern in intimate contact with the layer.

This invention relates to a stamper for pattern transfer, and its manufacturing method. More particularly, this invention relates to a stamper for pattern transfer and its manufacturing method which is employed to manufacture a product having a fine convex-concave (line-and-space) pattern on a surface of an information recording disk such as an information recording optical disk, information recording magnetic disk, etc.

With a rise of the recording density at a high speed in a field of information recording, further development in a micromachining technique has been demanded in a semiconductor field. Further, in a field of magnetic recording also, since a conventional continuous medium cannot still deal with coming demand of high density, a method of machining a recording medium (creating a pattern medium) has been studied. In these fields also, a similar micromachining technique has been demanded.

In mass-production of the above medium, using a photoresist or applying a lithography process to all the media is not practical from the viewpoint of throughput. As an alternative technique, applying an imprinting technique using a stamper serving as a mold for pattern transfer is more practical. This technique, if a stamper (master) serving as an original mold is once created by lithography, permits a large number of stampers belonging to a second generation (mother) and a third generation (child) to be manufactured from the master.

In the field of an optical disk, the various stamper manufacturing techniques as described above have been proposed. As the material of the stamper, in many cases, Ni has been employed. For example, it has been proposed in JP-A-2003-6946, JP-A-10-241214, or JP-A-5-205321.

However, the stamper manufactured by plating using a material having crystallinity such as Ni, because of its crystallinity, led to a phenomenon of occurrence of considerable fluctuation in an distal shape of the pattern formed on the stamper.

For example, as in JP-A-2003-6946, where a resist pattern is formed on a surface of a thick Ni film formed on a predetermined substrate and using this resist pattern as a mask, the Ni surface is etched to form a stamper, since Ni has crystal grains, etching proceeds as a unit of the crystal grain. In other words, a crystalline interface serves as a stopping phase for etching. Specifically, if apart of the grain is once etched away, the etching proceeds until it reaches the crystalline interface. The distal shape of the pattern of the stamper, therefore, can be formed only in a shape along the crystalline interface.

Further, for example, as in JP-A-10-241214, or JP-A-5-205321, where after a resist pattern is formed on a predetermined substrate and Ni is thick deposited from above by plating or sputtering, Ni is removed from the resist pattern to create a stamper, the side of the resist pattern is pushed aside so that the distal shape of the pattern of the stamper can be likewise formed only in a shape along the crystalline interface.

In this way, if fluctuation has occurred in the distal shape of the pattern of the stamper serving as an original mold, during the process of machining using the pattern transferred by this stamper, the fluctuation is transferred until the completion of the process (as the case may be, the fluctuation will be emphasized), and will be transferred on a final machining object layer.

Such fluctuation will occur irrespectively of a pattern size as long as the stamper material is similar. The influence of the fluctuation becomes obvious with progress of a fine pattern attendant on development of the high density and large capacity of a recording medium. This is a serious problem in the device whose characteristic depends on the pattern shape.

### SUMMARY OF THE INVENTION

This invention has been accomplished to solve the above problem. A first object of this invention is to provide a stamper for pattern transfer which has an improved linearity of the distal shape of the pattern formed on a stamper surface by depositing or etching and can deal with a fine pattern attendant on development of high density and large capacity. A second object of this invention is to provide a method for manufacturing a stamper for pattern transfer.

The stamper for pattern transfer according to this invention for attaining the first object is a stamper used as a mold for pattern transfer, wherein at least the convex extreme surface of the stamper is formed of a material with no crystalline peak in X-ray diffraction.

In accordance with this invention, since at least the convex extreme surface of the stamper is formed of a material with no crystalline peak in X-ray diffraction, a portion constituting the convex extreme surface of the stamper has no crystalline interface, thereby providing a stamper with the distal shape of the pattern having satisfactory linearity.

Further, the stamper for pattern transfer according to this invention is the stamper for pattern transfer described above, wherein at least a convex portion of the stamper is formed of a material with no crystalline peak in X-ray diffraction.

In this invention also, as in the stamper described above, since at least a convex portion of the stamper is formed of a material with no crystalline peak in X-ray diffraction, a portion constituting at least the convex portion of the stamper has no crystalline interface, thereby providing a stamper with the distal shape of a pattern having satisfactory linearity.

A method for manufacturing a stamper for pattern transfer according to this invention for attaining the above second object (also referred to as a first manufacturing method) is a method for manufacturing the stampers for pattern transfer described above, comprising the steps of:
forming a convex-concave pattern on a substrate;
forming, on the convex-concave pattern, a layer of a material with no crystalline peak in X-ray diffraction; and
finally removing the layer of the material with no crystalline peak in X-ray diffraction from the substrate and convex-concave pattern in intimate contact with the layer.

The method for manufacturing a stamper for pattern transfer according to this invention is the method for manufacturing a stamper for pattern transfer described above, wherein the convex-concave pattern is made of a resist material.

In accordance with this first manufacturing method according to this invention, since the layer of the material with no crystalline peak in X-ray diffraction has no crystalline interface, for example, even when the convex-concave pattern is made of the resist material, no deformation in the convex-concave portion does not occur owing to growth of crystalline grains occurs, thereby providing a stamper with the distal shape of the pattern having satisfactory linearity corresponding to the convex-concave pattern.

The method for manufacturing the stamper for pattern transfer according to this invention for attaining the above second object is the method for manufacturing the stamper for pattern transfer described above for attaining the above second object (also referred to as a second manufacturing method) comprising the steps of:
forming a convex-concave pattern on a substrate of a material with no crystalline peak in X-ray diffraction; and
etching the substrate using the convex-concave pattern as a mask.

In accordance with the second manufacturing method according to this invention, since the substrate of the material with no crystalline peak in X-ray diffraction is etched using the convex-concave pattern as a mask to manufacture the stamper, the distal shape of the pattern formed the surface of the stamper thus manufactured does not fluctuate along the crystalline interface, thereby providing a stamper with the distal shape of the pattern having a satisfactory linearity.

The method for manufacturing the stamper for pattern transfer according to this invention for attaining the above second object is the method for manufacturing the stamper for pattern transfer described above for attaining the above second object (also referred to as a third manufacturing method comprising the steps of:
forming, on a substrate, a layer of a material with no crystalline peak in X-ray diffraction having at least a thickness not smaller than a convex height of a desired stamper; and
etching the layer of the material with no crystalline peak using, as a mask, a convex-concave pattern formed thereon.

In accordance with the third manufacturing method according to this invention, since the layer of the material with no crystalline peak in X-ray diffraction is etched using the convex-concave pattern as a mask to manufacture the stamper, the distal shape of the pattern formed on the surface of the stamper thus manufactured does not fluctuate along the crystalline interface, thereby providing a stamper with the distal shape of the pattern having satisfactory linearity.

The method for manufacturing a stamper for pattern transfer according to this invention is the first, second or third manufacturing method, wherein the convex-concave pattern is made of a material with no crystalline peak in X-ray diffraction.

In accordance with this invention, since the convex-concave pattern is made of the material with no crystalline peak in X-ray diffraction, the convex-concave pattern or its residual distal shape does not fluctuate along the crystalline interface, thus forming it in a state with satisfactory linearity. For example, in the first manufacturing method, the layer of the material with no crystalline peak in X-ray diffraction is formed on the convex-concave pattern. Thus, there is provided a stamper with the distal shape of the pattern formed on the stamper thus manufactured having satisfactory linearity. In the second and third manufacturing method, where the stamper is manufactured using the convex-concave pattern as an etching mask, this convex-concave pattern or its residual distal shape does not fluctuate along the crystalline interface so that it is formed in a state with satisfactory linearity. Thus, there is provided a stamper with the distal shape of the pattern formed on the stamper thus manufactured having satisfactory linearity. Further, the second and third manufacturing method, where the stamper is manufactured using the convex-concave pattern as an etching mask, has an advantage that removal of the residue of the convex-concave pattern made of the above material is not particularly required.

The method for manufacturing the stamper for pattern transfer according to this invention for attaining the above second object is the method for manufacturing the stamper for pattern transfer described above for attaining the above second object (also referred to as a fourth manufacturing method comprising the steps of:
forming a layer of a material with no crystalline peak in X-ray diffraction on the surface of the stamper for pattern transfer according to this invention described above; and
finally removing the layer of the material with no crystalline peak in X-ray diffraction from the stamper in intimate contact with the layer.

In accordance with the fourth manufacturing method according to this invention, after the layer of a material with no crystalline peak in X-ray diffraction has been formed on the surface of the stamper, the layer is finally removed from the stamper in intimate contact with the layer, thereby manufacturing a new stamper. In the new stamper thus manufactured, the distal shape of the pattern on the surface thereof does not fluctuate along the crystalline interface and has satisfactory linearity. For this reason, if this method is adopted in order to manufacture the stamper belonging to the second generation (mother) or third generation (child), stampers each with the pattern with the distal shape having satisfactory linearity can be successively manufactured.

The method for manufacturing the stamper for pattern transfer according to this invention is the first manufacturing method or the fourth manufacturing method, wherein the layer of the material with no crystalline peak in X-ray diffraction is made of a conductive material, further comprising the step of forming a thick film by electrolytic plating after having formed the layer of the material.

In accordance with this invention, in the first manufacturing method or fourth manufacturing method, since the thick film is formed by electrolytic plating, the stamper can be effectively manufactured and the thick film thus formed can be made as an elaborate layer.

The method for manufacturing a stamper for pattern transfer according to this invention is the method for manufacturing the method for manufacturing a stamper for pattern transfer according to the first manufacturing method, wherein the convex-concave pattern is made of a material with no crystalline peak in X-ray diffraction, and the layer of the material with no crystalline peak in X-ray diffraction formed on the convex-concave pattern is made of a conductive material, further comprising the step of forming a thick film by electrolytic plating after having formed the layer of the material.

In accordance with this invention, in the first manufacturing method, the convex-concave pattern is formed of a material with no crystalline peak in X-ray diffraction, the layer of conductive material with no crystalline peak in X-ray diffraction is formed on the convex-concave pattern, and a thick film is formed thereon by electrolytic plating. Thus, the stamper with the distal shape of the pattern having satisfactory linearity can be effectively manufactured and the thick film thus formed can be made as an elaborate layer.

Incidentally, in this specification, the term “stamper for pattern transfer” or “stamper” generally refers to a mold for pattern transfer. As long as it is used as a transfer mold belonging to the master, mother, child, . . . as described above, it includes the stamper belonging to any generation.

Further, the “material with no crystalline peak in X-ray diffraction” includes not only a completely amorphous material but also a material having such a property which is microcrystalline or partially amorphous.

In accordance with the stamper for pattern transfer according to this invention as described above, since at least a portion constituting the convex extreme surface of the stamper has no crystalline interface, in the case of a fine pattern also, a stamper with the distal shape of the pattern having satisfactory linearity can be provided. Thus, using such a stamper, the fine pattern can be formed on a recording medium, thereby realizing the high density or large capacity of the recording medium.

In accordance with the method for manufacturing a stamper for pattern transfer according to the first manufacturing method of this invention, no deformation of the convex-concave pattern occurs owing to growth of crystalline grains so that a stamper with the distal shape of the pattern having satisfactory linearity can be provided. As a result, using the stamper thus manufactured, a fine pattern can be formed on a recording medium, and high density and large capacity of the recording medium can be realized.

In accordance with the method for manufacturing a stamper for pattern transfer according to the second and the third manufacturing method of this invention, the distal shape of the pattern of the surface of the stamper thus formed does not fluctuate along the crystalline interface so that a stamper with the distal shape of the pattern having satisfactory linearity can be provided. As a result, using the stamper thus manufactured, a fine pattern can be formed on a recording medium, and high density and large capacity of the recording medium can be realized.

In accordance with the method for manufacturing a stamper for pattern transfer according to the fourth manufacturing method of this invention, the stampers belonging to the second generation (mother) and the third generation (child) each with the distal shape of the pattern having satisfactory linearity can be successively manufactured. As a result, using the stamper thus manufactured, a fine pattern can be formed on a recording medium, and high density and large capacity of the recording medium can be realized.

### BRIEF DESCRIPTION OF THE DRAWINGS

FIGS. 1A to 1E are sectional views schematically showing exemplary various structures of the stamper according to this invention;

FIGS. 2A to 2F are schematic sectional views showing the respective steps of a method for manufacturing the stamper according to this invention;

FIGS. 3A to 3C are schematic sectional views showing the respective steps of another method for manufacturing the stamper according to this invention;

FIGS. 4A to 4E are schematic sectional views showing the respective steps of still another method for manufacturing the stamper according to this invention;

FIGS. 5A to 5C are schematic sectional views showing the respective steps of a further method for manufacturing the stamper according to this invention;

FIG. 6 is an SEM photograph of the stamper created in Example 1; and

FIG. 7 is an SEM photograph of the stamper created in Comparative Example.

### DETAILED DESCRIPTION OF THE PREFERRED EMBODIMENTS

A detailed explanation will be given of this invention on the basis of preferred embodiments.

(Stamper for Pattern Transfer)

The stamper for pattern transfer according to this invention (may be simply referred to as “stamper” in the specification) is employed as a mold for pattern transfer, and is characterized in that the extreme convex surface of the stamper is formed of at least a material with no crystalline peak in X-ray diffraction (hereinafter referred to as “α material” for simplicity).

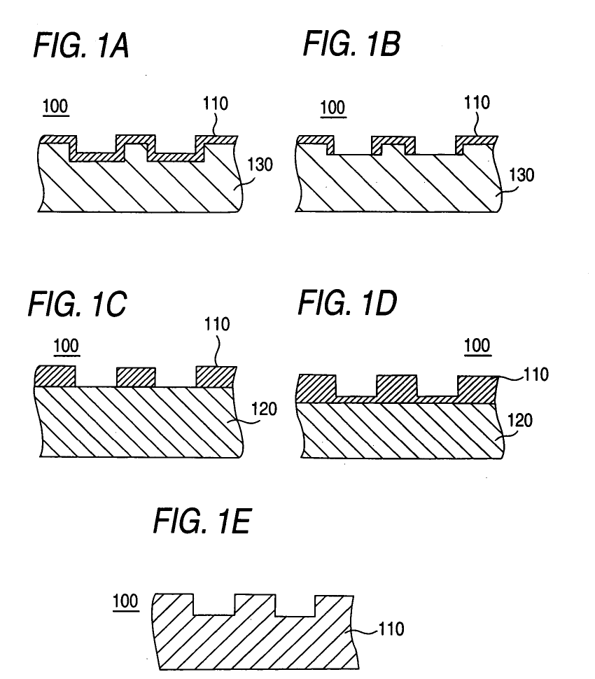

FIGS. 1A to 1E show structural examples of the stamper for pattern transfer according to this invention. In the examples shown in FIGS. 1A and 1B, only the extreme surface on the convex side of a stamper 100 is formed of a thin film of an α material 110. In the examples shown in FIGS. 1C and 1D, the portion including the entire convex is formed of a thick film of the α material 110. In the example shown in FIG. 1E, the entire stamper is formed of a bulk body of the α material 110.

In this invention, at least the convex extreme surface to be substantially subjected to imprinting for a workpiece has only to be formed of the α material 110. The stamper formed in such a structure does not have the crystalline interface at the convex extreme surface so that the distal shape of the pattern provides satisfactory linearity.

The α material 110 may be in the form of a thin or thick film, a layer or a bulk body. In FIG. 1, reference numeral 120 denotes a base material. The base material 120 serves as a substrate for the thick film of the α material 110 including the entire convex portion. In FIG. 1, reference 130 denotes a supporting layer. The supporting layer 130 serves as a layer which supports the thin film of the α material 110 constituting the convex extreme surface. It is needless to say that the laminated structure of the stamper according to this invention should not be limited to the manners shown in FIG. 1. For example, various functional layers or films may be arranged between the base material 120 and the layer of the α material 110 (this layer may be referred to as the α material layer), or between the supporting layer 130 and the α material layer.

Incidentally, where the α material layer inclusive of the “extreme surface” is formed as a thin film, its thickness is preferably at least 10 nm or more, more preferably 20 nm or more in order to obtain a stable characteristic for a long use although it depends on the shape of the stamper, particularly the size of the convex-concave portion, kind of the α material to be formed, or a creating technique.

In this invention, the material with no crystalline peak in X-ray diffraction (α material), although it depends on the form of the α material layer that is made as a thin film, a thick film, or a bulk body, and depend on its creating method, may be (1) an amorphous metal doped with Si, C, Ge, N, B, etc. such as TaSi, NiSi, TiN, TiC, TaN, TaGe and TaB, (2) an amorphous material doped with a refractory material, or (3) an amorphous material made by depositing a material having a high crystallizing temperature at a temperature lower than the crystallizing temperature.

The α material may be a hard amorphous material such as SiC. By using these materials, the strength of the stamper can be increased as compared with the conventional stamper using Ni. Thus, the endurance of the stamper is improved so that the number of times of using the stamper can be increased.

The method for creating the α material layer is not particularly limited. Various creating methods can be selected as the occasion demands so that the material used provides a required characteristic (no crystalline peak in X-ray diffraction). For example, in the case where the α material layer is formed as a thin film, sputtering, CVD, ion plating, etc. can be adopted as required. In the case where the α material layer is formed as a thick film, electrolytic plating, electroless plating, vacuum evaporation, etc. can be adopted as required. Further, in the case where the α material layer is formed as a bulk body, a known technique can be adopted according to the material.

Further, for example, as seen from FIGS. 1(a) and 1(b), where the stamper having the base material 120 is manufactured, the base material 120 is not particularly limited, but may be various metals such as Ni, Al, Cu, Mo, W, Fe and Cr, an alloy of these metals, glass, Si, SiC, SiN, carbon, or ceramics such as alumina and titania.

Incidentally, where adherence between these base materials 120 and the α material 110 is not satisfactory, as the occasion demands, on the basis of known techniques, the surface of the base material maybe subjected to various surface treatments such as plasma processing and coating of adhesive resin. Otherwise, a primer layer can be formed by sputtering, CVD, spray coating or ion plating.

Further, for example, as seen from FIGS. 1A and 1B, where the stamper having the supporting layer 130 is manufactured, the supporting layer 130 may be made of the same material as the base material 120 and may be subjected to the same processing as that for the base material 120. A preferable material for the supporting layer 130 is various metals such as Ni, Al, Cu, Fe and Cr or an alloy of these metals. A preferable creating method for the supporting layer 130 is electrolytic plating, electroless plating or vacuum evaporation. Incidentally, electrolytic plating, which can provide a more elaborate layer, is preferable to electroless plating. In this case, the α material is preferably conductive so that it can be subjected to electrolytic plating.

Such a stamper for pattern transfer according to this invention can be manufactured by the manufacturing methods as described below.

(First Manufacturing Method)

The stamper according to this invention can be manufactured by the first manufacturing method comprising the steps of forming a convex-concave pattern on a substrate, forming an α material layer on the convex-concave pattern, and finally removing the α material layer from the substrate and convex-concave pattern in intimate contact with the layer.

In this method, the convex-concave pattern formed on the substrate is not limited particularly, but may be made of various organic or inorganic materials. Concretely, the convex-concave pattern is preferably made of a resist material or the α material. The technique for creating the convex-concave pattern is preferably electron-beam photoresist or ultraviolet photoresist from the viewpoint of easiness of creation, easiness of machining and high resolution, etc. For example, a required shape of the convex-concave pattern can be formed by electron-beam lithography or ultraviolet lithography. Further, where the convex-convex pattern is made of the α material, when it is formed by etching, the distal shape of the convex-convex pattern does not fluctuate along the crystalline interface so that it can be formed to provide satisfactory linearity.

In this first manufacturing method, the α material formed on the convex-concave pattern is preferably made of a conductive material. This first manufacturing method also preferably includes a step of forming a thick film by electrolytic plating after having formed the layer of the conductive material. The first manufacturing method, which includes such a step, permits the stamper to be effectively manufactured and the thick film to be formed as an elaborate film.

Further, in this first manufacturing method, the convex-concave pattern is preferably made of the α material and the α material formed on the convex-concave pattern is preferably made of the conductive material. This first manufacturing method also preferably includes a step of forming a thick film by electrolytic plating after having formed the layer of the conductive material. The first manufacturing method, which includes such a step, permits the stamper with the distal shape of the pattern having satisfactory linearity to be effectively manufactured and the thick film to be formed as an elaborate film.

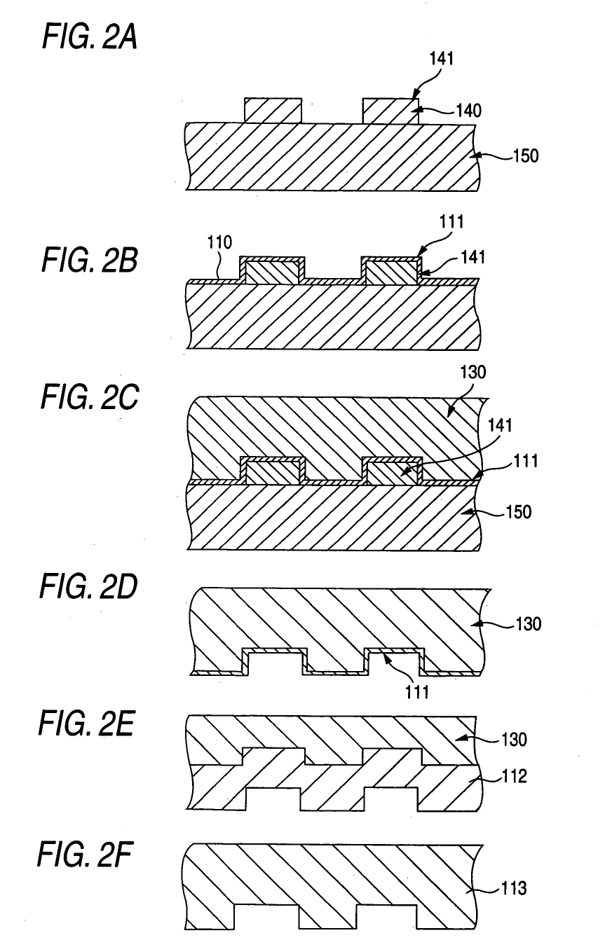

FIGS. 2A to 2F are schematic views showing the respective steps according to an embodiment of this manufacturing method. In this example, as seen from FIG. 2A, an electron-beam resist 140 having a thickness corresponding to the depth of a convex-concave pattern to be formed on a stamper, e.g. 100-200 nm is applied onto a supporting substrate 150. Thereafter, the electron-beam resist 140 is exposed and developed by an electron-beam plotting device to form a predetermined pattern. Incidentally, the convex-concave pattern 141 of the resist thus formed may be formed by not this method but by transfer/molding using a stamper having a really inverted convex-concave pattern shape.

Next, as seen from FIG. 2B, by DC magnetron sputtering for example, a thin film 111 made of the α material as indicated in the above items (1) to (3) and having a thickness of e.g. 10-50 nm is deposited on the convex-concave pattern 141 of the resist.

As seen from FIG. 2C, by plating, a supporting layer 130 is formed on the thin film 111 of the α material. Finally, as seen from FIG. 2D, the thin film 111 of the α material and the supporting layer 130 are removed from the supporting substrate 150 and convex-concave pattern 141, thereby completing the stamper. Further, after the removal, possible resist remaining on the side of the stamper can be washed away using e.g. tetrahydrofuran (THF).

In FIG. 2C, the α material was formed as the thin film. However, as seen from FIG. 2E, the α material may be formed as a thick film 112 having a thickness of e.g. 100-1000 nm. In this case, the supporting layer 130 is formed on the thick film 112. Further, the thick film 112 and supporting layer 130 are removed from the supporting substrate 150 and convex-concave pattern 141, thereby completing the stamper having the thick film 112 of the α material. Further, as seen from FIG. 2F, the α material may be formed as a thick film 113 having a thickness of e.g. 150-300 μm, thereby completing the stamper with no supporting layer.

In the first manufacturing method, as a technique for depositing the thin film 111 or thick films 112 and 113 which are made of the α material, DC magnetron sputtering or alternative techniques as described above can be appropriately selected. Further, as a technique of depositing the supporting layer 130, electrolytic plating, vacuum evaporation, etc. can be selected. In the case where the supporting layer 130 is formed by electrolytic plating, as described above, the α material is preferably the conductive material.

By manufacturing the stamper by the first manufacturing method, no deformation of the convex-concave pattern does not occur owing to growth of crystal grains so that a stamper can be provide in which the distal shape of the pattern having satisfactory linearity corresponding to the convex-concave pattern. As a result, using the stamper thus manufactured, a fine pattern can be formed on a recording medium, and high density and large capacity of the recording medium can be realized.

(Second Manufacturing Method)

The stamper according to this invention can also be manufactured by the second manufacturing method comprising the steps of forming a convex-concave pattern on a substrate of the α material and etching the substrate using the convex-concave pattern as a mask.

The substrate of the α material used in this method may be made of e.g. amorphous carbon, amorphous silicon and SiC. However, the substrate is not limited to these materials. Further, for example, for the amorphous carbon, an oxygen-series gas can be used as an etching gas. For the amorphous silicon, a fluorine-series gas such as SF₆ and CF₄ can be used as the etching gas. For the SiC, the fluorine-series gas or a mixed gas composed of the fluorine-series gas and oxygen-series gas can be used as the etching gas. The substrate of the α material can be etched using these etching gases. Further, the convex-concave pattern used when the substrate of the α material is etched is preferably appropriately selected from patterns having resistance to the etching gas used.

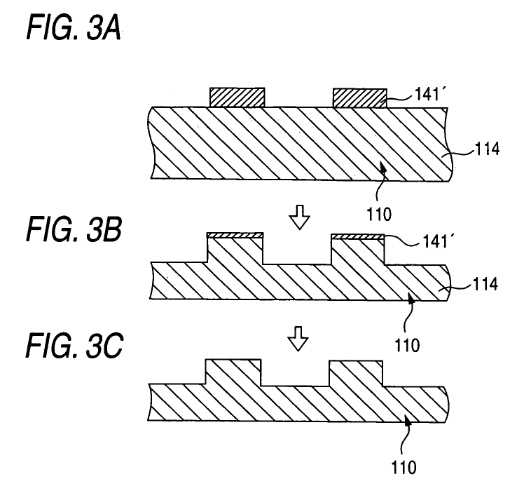

FIGS. 3A to 3C are schematic views showing the respective steps according to an embodiment of this second manufacturing method. In this example, as seen from FIG. 3A, after by e.g. DC magnetron sputtering, Si having an amorphous structure has been deposited on the substrate of amorphous carbon that is the α material, the electron-beam resist having a predetermined thickness is applied. Thereafter, the electron-beam resist is exposed and developed by an electron-beam plotting device to form a predetermined pattern. The resultant surface is subjected to ion beam etching to etch the Si deposited, thereby forming a convex-concave pattern 141′ of Si.

Next, as seen from FIG. 3B, by reactive ion etching using, as a mask, the convex-concave pattern 141′ of Si thus formed, the substrate 114 of amorphous carbon is etched by a depth of 100-200 mm. Finally, as seen from FIG. 3C, the residue of the convex-concave pattern 141′ of Si is removed, thus completing the stamper.

By manufacturing the stamper by the second manufacturing method, the distal shape of the pattern formed on the stamper surface does not fluctuate along the crystalline interface so that a stamper with the distal shape of the pattern having satisfactory linearity can be provided. As a result, using the stamper thus manufactured, a fine pattern can be formed on a recording medium, and high density and large capacity of the recording medium can be realized.

(Third Manufacturing Method)

The stamper according to this invention can also be manufactured by the third manufacturing method comprising the steps of forming, on a substrate, an α material layer having a thickness not smaller than a convex height of a desired stamper, and etching the α material layer using as a mask, a convex-concave pattern formed thereon.

In this method, in place of the substrate of the α material, a structural body is used in which a thick film of the α material is formed on a substrate of any optional material. This third manufacturing method is basically the same as the second manufacturing method except that at least the convex portion of the stamper is formed of the α material.

The α material employed in this method is preferably various α materials capable of forming the thick film of, e.g. amorphous carbon, amorphous silicon, TaSi, TaN, TiN, TiC, NiSi and SiC. However, the α material is not limited to these materials. Further, for example, for the amorphous carbon, the oxygen-series gas can be used as an etching gas. For the amorphous silicon, TaSi, TaN, TiN, and TiC, the fluorine-series gas can be used as the etching gas. For the NiSi, a carbonyl-series gas such as CO can be used as the etching gas. For the SiC, the fluorine-series gas or a mixed gas composed of the fluorine-series gas and oxygen-series gas can be used as the etching gas. The α material layer can be etched using these etching gases. Further, the mask used when the α material layer is etched is preferably appropriately selected from masks having resistance to the etching gas used.

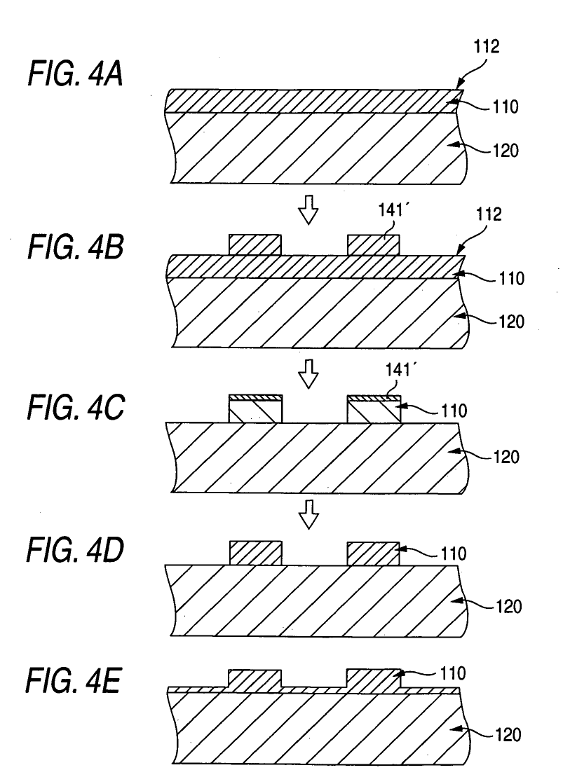

FIGS. 4A to 4E are schematic views showing the respective steps according to an embodiment of this third manufacturing method. In this example, as seen from FIG. 4A, by e.g. DC magnetron sputtering, a thick film (α material layer) of e.g. amorphous carbon that is the α material 110 is formed on a substrate 120 of any substance. The thick film 112 that is the α material layer has a thickness not smaller than a convex height of a desired stamper. The thickness may be e.g. 100-500 nm.

Next, after by e.g. DC magnetron sputtering, Si having an amorphous structure has been deposited on the thick film 112, the electron-beam resist having a predetermined thickness is applied. Thereafter, the electron-beam resist is exposed and developed by an electron-beam plotting device to form a predetermined pattern. The Si exposed on the resultant surface is ion-beam etched, thereby forming a convex-concave pattern 141′ of Si as shown in FIG. 4B. Next, as seen from FIG. 4C, by reactive ion etching from above, the thick film 112 of amorphous carbon is etched by a depth of e.g. 100-200 mm. Finally, as seen from FIG. 4D, the residue of the convex-concave pattern 141′ of Si is removed, thus completing the stamper.

Incidentally, as seen from FIG. 4D, it is not necessary to etch the entire height of the thick film 112 of the α material. As seen from FIG. 4E, a part of the height may be left in the concave portion as long as a predetermined convex height of the stamper is acquired.

By manufacturing the stamper by the third manufacturing method, using the convex-concave pattern as a mask, the α material layer is etched to manufacture the stamper so that the distal shape of the pattern formed on the stamper surface does not fluctuate along the crystalline interface. Thus, a stamper with the distal shape of the pattern having satisfactory linearity can be provided. As a result, using the stamper thus manufactured, a fine pattern can be formed on a recording medium, and high density and large capacity of the recording medium can be realized.

In the second and the third manufacturing method, the convex-concave pattern 141′ used when the α material is etched is preferably made of the material with no crystalline peak in the X-ray diffraction (different from the material to be etched) as exemplified above. Since the convex-concave pattern 141′ used as the mask is formed of such a material, when the convex-concave pattern 141 is formed by etching, or the α material 110 is etched using the convex-concave pattern 141 as a mask to form a desired pattern on the stamper surface, the distal shape of the convex-concave pattern 141′ or its residue does not fluctuate along the crystalline interface, Thus, it can be formed to provide satisfactory linearity. Further, the stamper with a desired pattern has an advantage that removal of the residue of the convex-concave pattern 141′ of the above material is not required.

(Fourth Manufacturing Method)

In the case where the stamper is a stamper belonging to a second generation, third generation, . . . , the stamper according to this invention can also be manufactured by the fourth manufacturing method comprising the steps of forming an α material layer on the surface of the stamper according to this invention previously formed, and finally removing the α material layer from the stamper in intimate contact therewith.

In this fourth manufacturing method, the α material layer is preferably made of a conductive material. The fourth manufacturing method preferably includes a step of forming a thick film after having formed the α material layer. The fourth manufacturing method, which includes such a step, permits the thick film thus formed to be an elaborate layer.

The α material which can be used in the fourth manufacturing method is basically the same as that in the first manufacturing method. In the manufacturing process also, the fourth manufacturing method can be carried out similarly to the first manufacturing method except that the stamper according to this invention previously manufactured is used in place of a mold constructed of the supporting substrate 150 and the convex-concave pattern 141 of the resist.

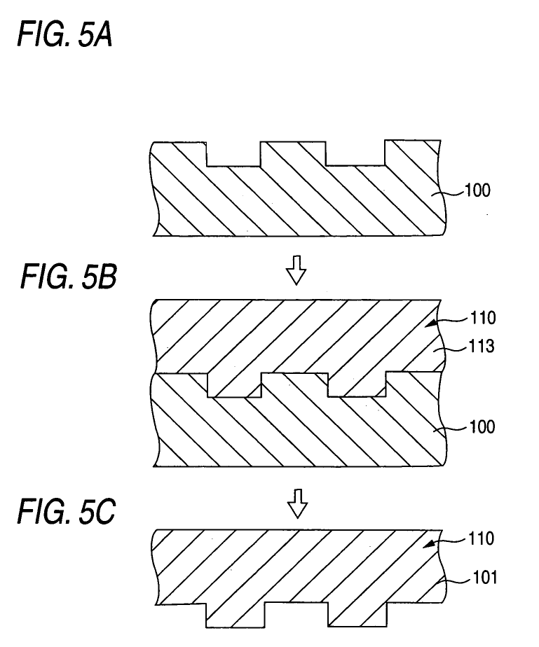

FIGS. 5A to SC are schematic views showing the respective steps according to an embodiment of this fourth manufacturing method. As seen from FIG. 5B, a thick film 113 of the α material 110 is formed on the mold face of the stamper 100 according to this invention previously formed shown in FIG. 5A. Thereafter, as seen from FIG. 5C, the thick film 113 is removed from the stamper, thereby forming a new stamper 101. Incidentally, in FIG. 5, although the stamper serving as the mold and the new stamper 101 are both shown as the α material 110 alone, as understood from the above description, these stampers can be manufactured in various forms shown in FIG. 1.

In accordance with the fourth manufacturing method, the new stamper thus manufactured, in which the distal shape of the pattern formed on the surface of the stamper does not fluctuate along the crystalline interface, provides the distal shape of the pattern with satisfactory linearity. By adopting this method in order to manufacture the stamper belonging to the second generation (mother) and the third generation (child), stampers each with the distal shape of the pattern having satisfactory linearity can be successively manufactured. The stamper according to this invention thus manufactured permits the pattern formed on the surface to provide the distal shape having satisfactory linearity, and can deal with a fine pattern due to the development of high density and large capacity of the recording medium. Thus, the stamper according to this invention can applied to manufacturing various devices inclusive of an information recording optical disk, information recording magnetic disk and a magneto-optic recording disk.

### EXAMPLE

A concrete explanation will be given of this invention in comparison between its examples and comparative examples.

### Example 1

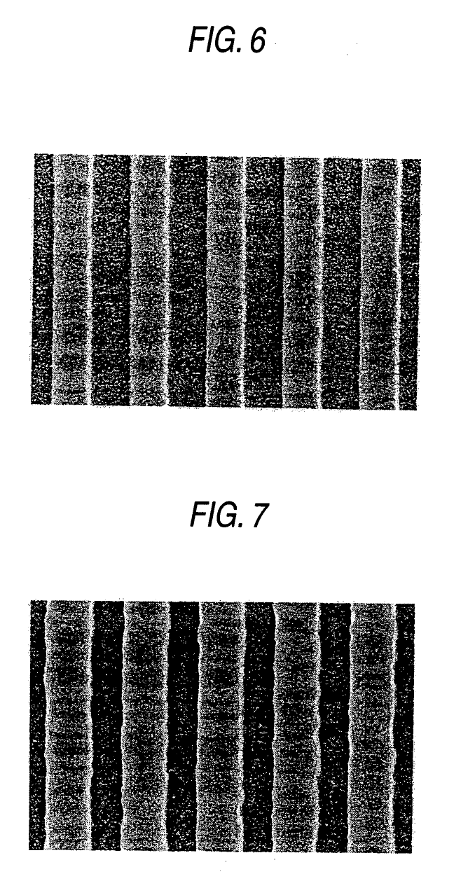

As seen from FIG. 2A, an electron-beam resist 140 having a thickness of about 100 nm was applied onto a supporting substrate 150 of e.g. a Si substrate. Thereafter, the electron-beam resist 140 was exposed and developed by the electron-beam plotting device to form a convex-concave pattern 141 of the resist having a line width of about 110 nm and a space width of about 90 nm. By DC magnetron sputtering, a thin film 111 made of the α material was deposited on the convex-concave pattern 141. The α material is TaSi with a composition ratio of 4:1 (atomic ratio) having an amorphous structure. The thin film 111 has a thickness of about 50 nm. Next, by electrolytic plating, a supporting layer 130 of Ni having a thickness of about 300 μm was deposited on the thin film 111. Finally, Ni serving as the supporting layer 130 and TaSi serving as the α material thin film 111 were removed from the Si substrate (supporting substrate 150), thereby creating the stamper of Example 1 (FIG. 2D). The SEEM photograph of the pattern shape of this stamper is shown in FIG. 6. In FIG. 6, a whitish portion is a convex portion, a blackish portion is a concave portion and an interface therebetween is a distal shape. As seen from FIG. 6, the distal shape of the pattern formed on the surface of the stamper in Example 1 provides a more excellent linearity than Comparative Example 1 described later.

### Example 2

As seen from FIG. 3A, as the substrate 114 of the α material, a carbon substrate having the amorphous structure was adopted. By DC magnetron sputtering, a Si film having the amorphous structure and a thickness of about 20 nm was deposited on the substrate 114. Thereafter, the electron-beam resist having a thickness of about 100 nm was applied onto the Si film. The electron-beam resist was exposed and developed by the electron-beam plotting device to form a resist pattern having a line width of about 110 nm and a space width of about 90 nm. The resultant surface is subjected to ion beam etching to etch the Si film deposited, thereby forming a convex-concave pattern 141′ of Si. Reactive ion etching was performed using, as a mask, the convex-concave pattern 141′ of Si. In this case, the carbon substrate was etched by about 100 nm using an O2 gas as a reactive gas, thereby creating the stamper according to Example 2 (FIG. 3C).

### Example 3

The stamper according to Example 3 was created in the same manner as that for Example 1 except that the thin film 111 of the α material 111 of SiC having a thickness of about 50 nm was deposited in the method for manufacturing the stamper according to Example 1. Specifically, after the convex-concave pattern 141 of the resist having a line width of about 110 nm and a space width of about 50 nm has been formed, a film of the α material of SiC having a thickness of about 50 nm was deposited thereon. Thereafter, by electrolytic plating, the supporting layer 130 of Ni having a thickness of about 300 μm was deposited on the thin film 111. Finally, Ni serving as the supporting layer 130 and SiC serving as the α material thin film 111 were removed from the Si substrate, thereby creating the stamper of Example 3. The stamper thus created, whose surface is made of a hard amorphous material of SiC, was a stamper with excellent endurance.

### Comparative Example

The stamper according to Comparative Example was created in the same manner as that for Example 1 except that the thin film 111 of the α material 110 was not deposited by DC magnetron sputtering in the method for manufacturing the stamper according to Example 1. Specifically, after the convex-concave pattern 141 of the resist having a line width of about 110 nm and a space width of about 90 nm has been formed, without forming the α material layer, a film of pure Ni having a thickness of about 50 nm is directly deposited on the convex-concave pattern 141 by DC magnetron sputtering. Thereafter, another Ni film having a thickness of 300 μm was further deposited by electrolytic plating. The Ni films were removed from the Si substrate, thereby creating the stamper according to Comparative Example. The SEM photograph of the pattern shape of the stamper according to Comparative Example is shown in FIG. 7.

1. A stamper used as a mold for pattern transfer, including a convex-concave pattern,
wherein at least convex extreme surface of the stamper is formed of a material with no crystalline peak in X-ray diffraction.

2. A stamper according to claim 1, wherein at least a convex portion of the stamper is formed of a material with no crystalline peak in X-ray diffraction.

3. A method for manufacturing a stamper for pattern transfer, comprising the steps of:
forming a convex-concave pattern on a substrate;
forming, on the convex-concave pattern, a layer of a material with no crystalline peak in X-ray diffraction; and
finally removing the layer of the material with no crystalline peak in X-ray diffraction from said substrate and convex-concave pattern in intimate contact with the layer.

4. A method for manufacturing a stamper for pattern transfer according to claim 3, wherein said convex-concave pattern is made of a resist material.

5. A method for manufacturing a stamper for pattern transfer according to claim 3, wherein said convex-concave pattern is made of a material with no crystalline peak in X-ray diffraction.

6. A method for manufacturing a stamper for pattern transfer according to claim 3, wherein said layer of said material with no crystalline peak in X-ray diffraction is made of a conductive material, and
the method further comprising the step of forming a thick film by electrolytic plating after having formed the layer of said material.

7. A method for manufacturing a stamper for pattern transfer according to claim 3, wherein said convex-concave pattern is made of a material with no crystalline peak in X-ray diffraction, and said layer of said material with no crystalline peak in X-ray diffraction formed on said convex-concave pattern is made of a conductive material, and
the method further comprising the step of forming a thick film by electrolytic plating after having formed the layer of said material.

8. A method for manufacturing a stamper for pattern transfer, comprising the steps of:
forming a convex-concave pattern on a substrate of a material with no crystalline peak in X-ray diffraction; and
etching said substrate using said convex-concave pattern as a mask.

9. A method for manufacturing a stamper for pattern transfer according to claim 8, wherein said convex-concave pattern is made of a material with no crystalline peak in X-ray diffraction.

10. A method for manufacturing a stamper for pattern transfer, comprising the steps of:
forming, on a substrate, a layer of a material with no crystalline peak in X-ray diffraction having at least a thickness not smaller than a convex height of a desired stamper; and
etching said layer of the material with no crystalline peak using a convex-concave pattern formed thereon as a mask.

11. A method for manufacturing a stamper for pattern transfer according to claim 10, wherein said convex-concave pattern is made of a material with no crystalline peak in X-ray diffraction.

12. A method for manufacturing a stamper for pattern transfer comprising the steps of:
forming a layer of a material with no crystalline peak in X-ray diffraction on the surface of the stamper for pattern transfer including a convex-concave pattern, in which at least convex extreme surface of the stamper is formed of a material with no crystalline peak in X-ray diffraction;
finally removing said layer of the material with no crystalline peak in X-ray diffraction from said stamper in intimate contact with the layer.

13. A method for manufacturing a stamper for pattern transfer according to claim 12, wherein said layer of said material with no crystalline peak in X-ray diffraction is made of a conductive material, further comprising the step of forming a thick film by electrolytic plating after having formed the layer of said material.
